(19) United States
(12) Patent Application Publication
(10) Pub. No.: US 2019/0258593 A1
(43) Pub. Date: Aug. 22, 2019

(54) MEMORY CONTROLLER AND OPERATING METHOD THEREOF

(71) Applicant: SK hynix Inc., Gyeonggi-do (KR)

(72) Inventor: Seung Wan JUNG, Gyeonggi-do (KR)

(21) Appl. No.: 16/123,657

(22) Filed: Sep. 6, 2018

(30) Foreign Application Priority Data
Feb. 20, 2018 (KR) 10-2018-0019906

(51) Int. Cl. G06F 13/16; G11C 7/10; G06F 3/06; G11C 7/22

(52) U.S. Cl. CPC G06F 13/161; G11C 7/1096; G11C 7/1084; G11C 7/1057; G11C 7/22; G06F 3/0656

(57) ABSTRACT

In a memory controller for controlling a write operation of a memory device in response to a write request received from a host, the memory controller includes a write buffer and a response message control circuit. The write buffer stores write data received from the host together with the write request. The response message control circuit generates a response message corresponding to the write request and transfers the response message to the host. Also, the response message control circuit determines a response time to transfer the response message, based on a utilization rate of the write buffer.

### CROSS-REFERENCE TO RELATED APPLICATION

The present application claims priority under 35 U.S.C. § 119(a) to Korean patent application number 10-2018-0019906, filed on Feb. 20, 2018, which is incorporated herein by reference in its entirety.

### BACKGROUND

### Field of Invention

Various embodiments of the present disclosure generally relate to an electronic device. Particularly, the embodiments relate to a memory controller and an operating method thereof.

### Description of Related Art

Memory devices may be formed in a two-dimensional structure in which strings are arranged horizontally, or be formed in a three-dimensional structure in which strings are arranged vertically. A three-dimensional semiconductor device was devised in order to overcome the degree of integration limit in two-dimensional semiconductor devices. A three-dimensional semiconductor device may include a plurality of memory cells vertically stacked on a semiconductor substrate. Operation of the memory device may be controlled by a memory controller.

### SUMMARY

Embodiments provide a memory controller capable of reducing a variation in write latency.

Embodiments also provide an operating method of a memory controller capable of reducing a variation in write latency.

According to an aspect of the present disclosure, there is provided a memory controller for controlling a write operation of a memory device in response to a write request received from a host, the memory controller including: a write buffer configured to store write data received from the host together with the write request; and a response message control circuit configured to generate a response message corresponding to the write request and transfer the response message to the host, wherein the response message control circuit determines a response time to transfer the response message, based on a utilization rate of the write buffer.

The utilization rate of the write buffer may be defined as a ratio of a total capacity of the write buffer to a current use of the write buffer. The response time may be defined as a time interval from when the write request is provided to the memory controller from the host to when the response message is transferred to the host.

The response time may be determined to be relatively long when the utilization rate of the write buffer is relatively high.

When the utilization rate of the write buffer is less than or equal to a first threshold value, the response message control circuit may determine the response time to be 0 and immediately transfer the response message to the host when the write data is stored in the write buffer. When the utilization rate of the write buffer is greater than the first threshold value, the response message control circuit may determine a first time as the response time.

The response message control circuit may include: a buffer monitor configured to determine the response time by monitoring the utilization rate of the write buffer; a response time storage configured to store the response time; and a response message generator configured to generate a response message corresponding to the write request, and output the response message based on the response time stored in the response time storage.

The buffer monitor may determine the response time in proportion to the utilization rate of the write buffer.

The buffer monitor may determine the response time in a stepwise manner with respect to the utilization rate of the write buffer.

When the utilization rate of the write buffer is less than or equal to a second threshold value, the buffer monitor may determine the response time to be 0. When the utilization rate of the write buffer is greater than the second threshold value, the buffer monitoring section may determine the response time as a linear function with respect to the utilization rate of the write buffer.

When the utilization rate of the write buffer is less than or equal to a third threshold value, the buffer monitor may determine the response time to be 0. When the utilization rate of the write buffer is greater than the third threshold value and is less than a fourth threshold value, the buffer monitor may determine the response time to be a second time. When the utilization rate of the write buffer is greater than the fourth threshold value, the buffer monitor may determine the response time as a linear function with respect to the utilization rate of the write buffer.

According to another aspect of the present disclosure, there is provided a method for operating a memory controller for controlling an operation of a memory device, the method including: receiving, from a host, a write request and write data corresponding thereto; storing the write data in a write buffer; and transferring a response message corresponding to the write request to the host according to a response time determined based on a utilization rate of the write buffer.

The transferring of the response message corresponding to the write request to the host according to the response time determined based on the utilization rate of the write buffer may include: receiving the utilization rate from the write buffer; determining whether the utilization rate is greater than a first threshold value; and transferring a response message to the host based on a determination result.

In the transferring of the response message to the host, based on the determination result, when the utilization rate is greater than the first threshold value, the response message may be transferred to the host after waiting a first time period, and when the utilization rate is less than or equal to the first threshold value, the response message may be immediately transferred to the host.

The transferring of the response message corresponding to the write request to the host according to the response time determined based on the utilization rate of the write buffer may include: receiving the utilization rate from the write buffer; determining the response time corresponding to the utilization rate, wherein the determined response time includes a first wait time; and transferring the response message to the host after the first wait time elapses.

In the determining of the response time, the response time may be determined in proportion to the utilization rate.

In the determining of the response time, the response time may be determined in a stepwise manner with respect to the utilization rate.

In the determining of the response time, when the utilization rate is less than or equal to a second threshold value, the response time is determined to be immediate, and when the utilization rate is greater than the second threshold value, the response time may be determined as a linear function with respect to the utilization rate.

In the determining of the response time, when the utilization rate is less than or equal to a third threshold value, the response time is determined to be immediate, when the utilization rate is greater than the third threshold value and is less than a fourth threshold value, a response time is determined to include a second wait time, and when the utilization rate is greater than the fourth threshold value, the response time may be determined as a linear function with respect to the utilization rate.

According to an aspect of the present disclosure, there is provided a memory system including a memory device; a buffer configured to buffer data provided from an external source; and a controller. The controller is configured to: control the memory device to perform a write operation with the buffered data in response to a request from the external source; and provide a response of the request to the external source at a response time, which is after the controller receives the request. The controller determines the response time based on a currently available capacity of the buffer.

### BRIEF DESCRIPTION OF THE DRAWINGS

Various embodiments will now be described more fully with reference to the accompanying drawings; however, elements and features may be arranged or configured differently than shown or described herein. Thus, the present invention is not limited to the embodiments set forth herein. Rather, these embodiments are provided so that this disclosure is thorough and complete and fully conveys the scope of the embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a diagram illustrating a memory system including a memory controller according to an embodiment of the present disclosure.

FIG. 2 is a block diagram illustrating in detail the memory controller of FIG. 1.

FIG. 3 is a diagram illustrating a memory device of FIG. 1.

FIG. 4 is a block diagram illustrating a memory controller according to an embodiment of the present disclosure.

FIG. 5 is a block diagram illustrating an embodiment of a response message control circuit of FIG. 4.

FIG. 6 is a flowchart illustrating an operating method of the memory controller according to an embodiment of the present disclosure.

FIG. 7 is a graph illustrating a response time determined according to an embodiment of the present disclosure.

FIG. 8 is a flowchart illustrating a method for transferring a response message according to the embodiment shown in FIG. 7.

FIG. 9 is a flowchart illustrating a method for transferring a response message according to another embodiment of the present disclosure.

FIG. 10 is a graph illustrating response time increased in proportion to utilization rate of a write buffer according to an embodiment of the present disclosure.

FIG. 11 is a graph illustrating response time increased in a stepwise manner in proportion to utilization rate of the write buffer according to an embodiment of the present disclosure.

FIG. 12 is a graph illustrating response time linearly increased in a certain section of utilization rate of the write buffer according to an embodiment of the present disclosure.

FIG. 13 is a graph illustrating response time applied to three sections obtained by dividing utilization rate of the write buffer according to an embodiment of the present disclosure.

FIG. 14 is a block diagram illustrating another embodiment of the memory system.

FIG. 15 is a diagram illustrating another embodiment of the memory system including the memory controller shown in FIGS. 1 and 2.

FIG. 16 is a diagram illustrating another embodiment of the memory system including the memory controller shown in FIGS. 1 and 2.

FIG. 17 is a diagram illustrating another embodiment of the memory system including the memory controller shown in FIGS. 1 and 2.

FIG. 18 is a diagram illustrating another embodiment of the memory system including the memory controller shown in FIGS. 1 and 2.

### DETAILED DESCRIPTION

In the following detailed description, embodiments of the present disclosure are shown and described, simply by way of example. As those skilled in the art would realize, the described embodiments may be modified in various different ways, all without departing from the spirit or scope of the present disclosure. Accordingly, the drawings and description are to be regarded as illustrative in nature and not restrictive.

In the entire specification, when an element is referred to as being “connected” or “coupled” to another element, it can be directly connected or coupled to the another element or be indirectly connected or coupled to the another element with one or more intervening elements interposed. In addition, when an element is referred to as “including” a component, this indicates that the element may further include one or more other components rather than excluding such other component(s), unless the context indicates otherwise. Also, throughout the specification, reference to “an embodiment” or the like is not necessarily to only one embodiment, and different references to “an embodiment” or the like are not necessarily to the same embodiment(s).

Various embodiments of the present disclosure will be described in detail with reference to the accompanying drawings. The same reference numerals are used to designate the same elements as those shown in other drawings. In the following descriptions, only portions necessary for understanding operations according to the exemplary embodiments may be described; description of known technical material may be omitted so as to not obscure important concepts of the embodiments.

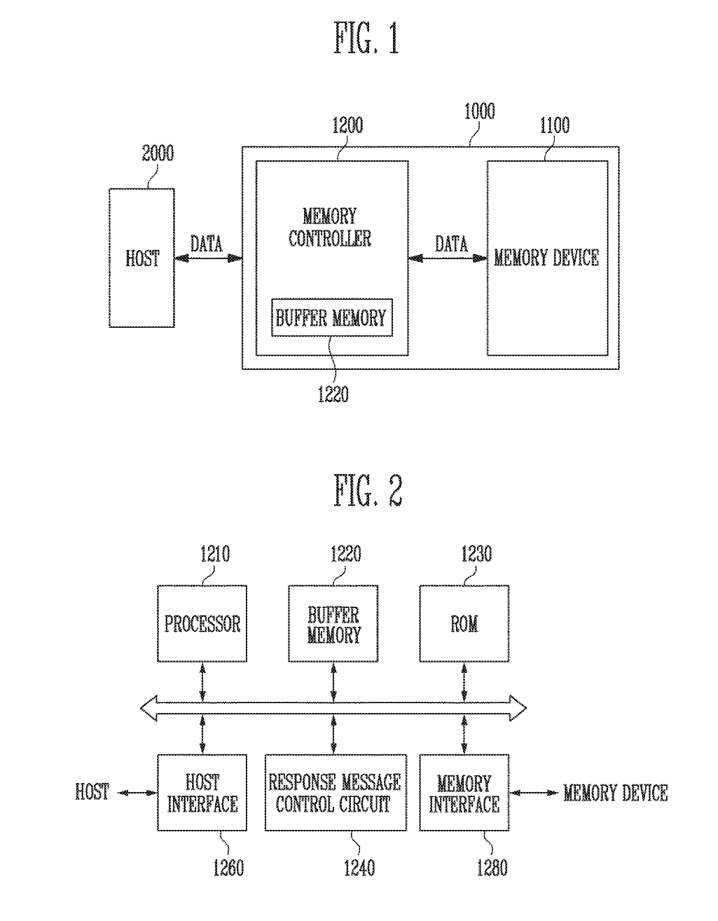

FIG. 1 is a diagram illustrating a memory system including a memory controller according to an embodiment of the present disclosure.

Referring to FIG. 1, the memory system 1000 may include a memory device 1100 for storing data and a memory controller 1200 for controlling the memory device 1100 under the control of a host 2000.

The host 2000 may communicate with the memory system 1000 by using an interface protocol such as Peripheral Component Interconnect-Express (PCI-E), Advanced Technology Attachment (ATA), Serial ATA (SATA), Parallel ATA (PATA), or Serial Attached SCSI (SAS). Interface protocols between the host 2000 and the memory system 1000 are not limited to the above-described examples; one of other interface protocols such as a Universal Serial Bus (USB), a Multi-Media Card (MMC), an Enhanced Small Disk Interface (ESDI), and Integrated Drive Electronics (IDE) may be used.

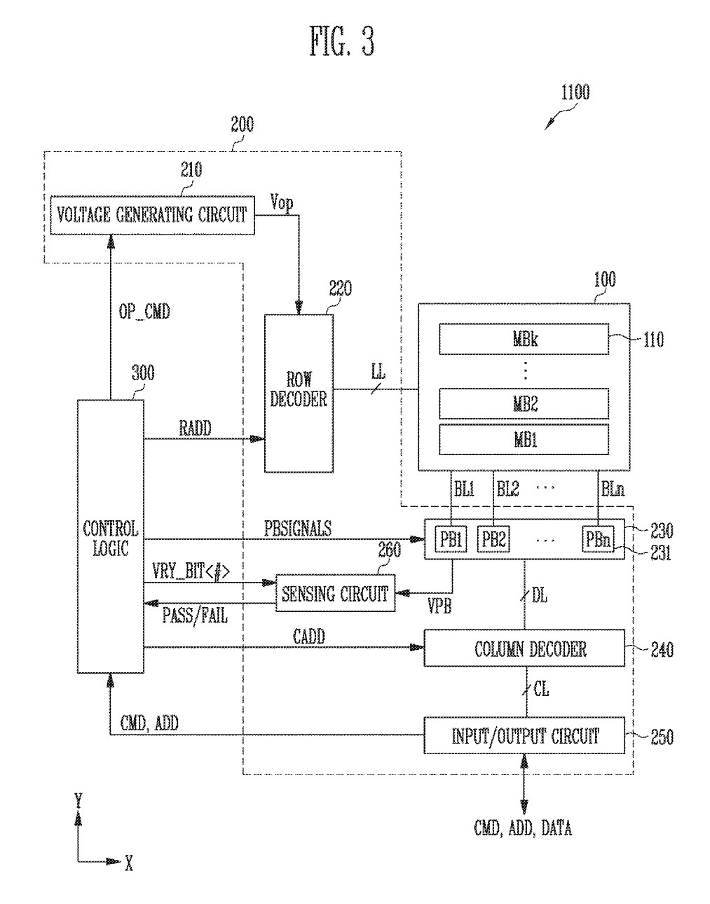

The memory controller 1200 may control overall operations of the memory system 1000, and control data exchange between the host 2000 and the memory device 1100. For example, the memory controller 1200 may program or read data by controlling the memory device 1100 in response to a request from the host 2000. Also, the memory controller 1200 may store information of main memory blocks and sub-memory blocks, which are included in the memory device 1100, and select the memory device 1100 to perform a program operation on a main memory block or a sub-memory block according to the amount of data loaded for the program operation. In some embodiments, the memory device 1100 may include a Double Data Rate Synchronous Dynamic Random Access Memory (DDR SDRAM), a Low Power Double Data Rate 4 (LPDDR4) SDRAM, a Graphics Double Data Rate (GDDR) SRAM, a Low Power DDR (LPDDR), a Rambus Dynamic Random Access Memory (RDRAM), and/or a flash memory. A detailed, exemplary configuration of the memory controller 1200 will be described with reference to FIG. 2.

The memory controller 1200 may include a buffer memory 1220. The buffer memory 1220 may temporarily store data DATA received from the host 2000 or data DATA received from the memory device 1100.

As an example, when a write request and write data corresponding thereto are received from the host 2000, the memory controller 1200 temporarily stores the write data in the buffer memory 1220. Subsequently, the memory controller 1200 translates a logical address received together with the write request from the host 2000 into a physical address. Also, the memory controller 1200 transfers, to the memory device 1100, the translated physical address and the write data stored in the buffer memory 1220 together with a write command. The memory device 1100 performs a write operation, based on the received write data and the received physical address.

As another example, when a read request is received from the host 2000, the memory controller 1200 translates a logical address received together with the read request into a physical address. Also, the memory controller 1200 transfers, to the memory device 1100, the translated physical address together with a read command. The memory device 1100 performs a read operation, based on the received physical address. Accordingly, read data is transferred from the memory device 110 to the memory controller 1200. The memory controller 1200 temporarily stores the received read data in the buffer memory 1220. Subsequently, the memory controller 1200 transfers the read data stored in the buffer memory 1220 to the host 2000.

In the above-described process, the data transfer speed between the host 2000 and the memory controller 1200 may be different from the data processing speed of the memory device 1100. In general, while the data transfer speed between the host 2000 and the memory controller 1200 is relatively fast, the data processing speed of the memory device 1100 is relatively slow. For example, the data write speed of the memory device 1100 is relatively slow. Therefore, when a write request and write data, which are consecutive, are received from the host 2000, the memory device 1100 may not process them at the same time. The memory controller 1200 may include the buffer memory 1220 buffer data flow between the host 2000 and the memory device 1100 through the memory controller 1200.

In a write operation, a write buffer in which write data is to be stored may be included in the buffer memory 1220. A partial area of the buffer memory 1220 may be allocated to constitute the write buffer. When a write request and write data are received from the host 2000, the memory controller 1200 temporarily stores the received write data in the write buffer, and transfers a response message to the host 2000 after the write data is completely stored in the write buffer. The host 2000 waits to receive the response message after the write request and the write data are transferred to the memory controller 1200. Even in a situation in which the host 2000 is to additionally transfer a subsequent write request and subsequent write data to the memory controller 1200, the host 2000 does not transfer such request and data to the memory controller 1200 until before the host 2000 receives the response message. When the host 2000 receives the response message from the memory controller 1200, the host 2000 transfers the subsequent write request and the subsequent write data to the memory controller 1200.

In general, the memory controller 1200 immediately transfers the response message to the host 2000 after the received write data is stored in the write buffer. Therefore, when consecutive write requests are received from the host 2000, the entire write buffer is fully filled with data. Although a write request and write data are received from the host 2000 when the write buffer is fully filled with data, the memory controller 1200 cannot store the received write data in the write buffer. The memory controller 1200 does not transfer the response message to the host 2000 until the full write buffer becomes partially or completely empty and available for buffering additional write data. When at least one portion of the data stored in the write buffer is transferred to the memory device 1100 such that a partial space of the write buffer is empty, the memory controller 1200 may transfer he response message to the host 2000.

Therefore, in such a situation, “write latency” between the host 2000 and the memory controller 1200 is periodically increased. In this specification, the “write latency” refers to a time interval from when the host 2000 transfers a write request to the memory controller 1200 to when the host 2000 receives the response message from the memory controller 1200.

A situation may repeatedly occur, in which the memory controller 1200 does not transfer the response message to the host 2000 since the write buffer is fully filled with data. As a result, there appears a large variation in write latency between the host 2000 and the memory controller 1200, which results in degradation of the operation performance of the memory system 1000.

The memory controller 1200 according to an embodiment of the present disclosure determines a response time based on a utilization rate of the write buffer. The response time may mean a time interval from when the write request is provided to the controller 1200 from the host 2000 to when the response message is transferred to the host 2000. The utilization rate of the write buffer may be defined as a ratio of a total capacity of the write buffer to a currently occupied capacity of the write buffer.

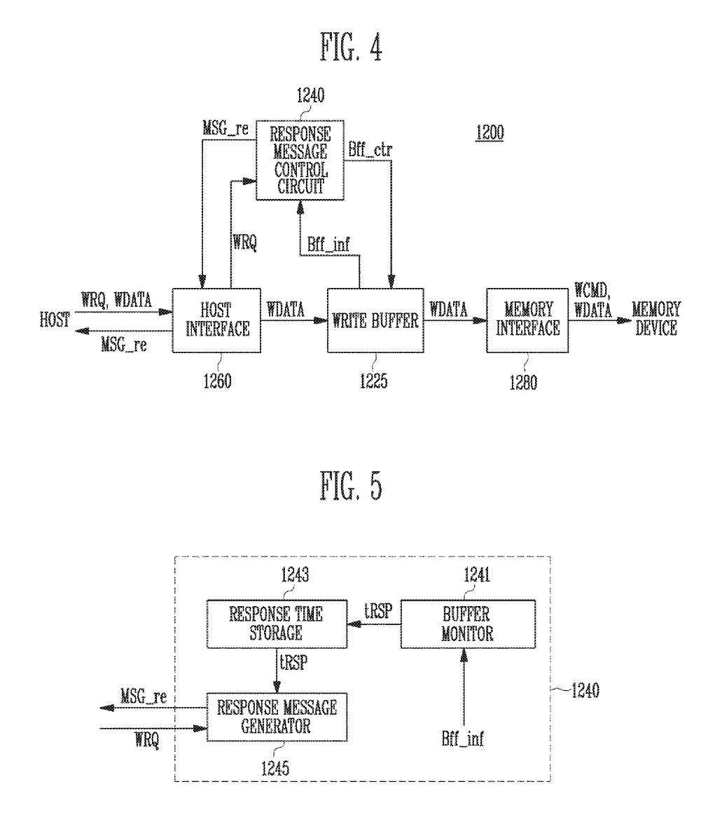

For example, the response time is set short when the utilization rate of the write buffer is low, and is set long when the utilization rate of the write buffer is high. Accordingly, the variation in write latency is decreased from the point of view of the host 2000. Consequently, the operation performance of the memory system 1000 is improved. According to embodiments of the present disclosure, a configuration of controlling the response time in response to the write request will be described later with reference to FIGS. 4 to 13.

The memory controller 1200 includes a flash translation layer (‘FTL’). The FTL provides an interface between an external device and the memory device 1100 such that the memory device 1100 is efficiently used. For example, the FTL may perform a function of translating a logical address received from the host 2000 into a physical address used in the memory device 1100. The FTL may perform the above-described address translation operation through a mapping table. As an example, the physical address indicates the logical position of a storage area, which is managed by the host 2000, and the physical address indicates the physical position of the memory device 1100, which is managed by the memory controller 1200.

The FTL may perform an operation such as wear leveling or garbage collection (GC) such that the memory device 1100 can be efficiently used. As an example, the wear leveling indicates an operation of managing program/erase numbers of a plurality of memory blocks included in the memory device 1100 such that the program/erase numbers of the plurality of memory blocks are uniform. As an example, the garbage collection (GC) indicates an operation of moving valid pages of select memory blocks among the plurality of memory blocks in the memory device 1100 to another memory block and then erasing the select memory blocks. The erased memory blocks may be used as free blocks. The FTL may secure free blocks of the memory device 1100 by performing the garbage collection.

The memory device 1100 may perform a program, read or erase operation under the control of the memory controller 1200. A detailed, exemplary configuration and operation of the memory device 1100 will be described with reference to FIG. 3.

FIG. 2 is a block diagram illustrating in detail the memory controller of FIG. 1.

Referring to FIGS. 1 and 2 together, the memory controller 1200 includes a processor 1210, a buffer memory 1220, a ROM 1230, a host interface 1260, a response message control circuit 140, and a memory interface 1280.

The processor 1210 may control overall operations of the memory controller 1200. The buffer memory 1220 may be configured as a working memory of the memory controller 1200, or be used as a cache memory. In an embodiment, the buffer memory 1220 may be configured as an SRAM. In another embodiment, the buffer memory 1220 may be configured as a DRAM.

The buffer memory 1220 may store an FTL provided in a software format. The FTL stored in the buffer memory 1220 may be driven by the processor 1210. Also, the buffer memory 1220 may include a write buffer (not shown) as described above. Write data from the host may be temporarily stored in the write buffer. Data read from the memory device 1100 may also be temporarily stored in the buffer memory 1220.

The ROM 1230 may store, in a firmware format, various information required when the memory controller 1200 operates.

As an example, a data management unit of the external device, i.e., the host 2000, may be different from that of the memory device 1100. For example, the host 2000 may manage data based on a sector unit. That is, the host 2000 may write and read data based on the sector unit. On the other hand, the memory device 1100 may manage data based on a page unit. That is, the memory device 1100 may write and read data based on the page unit. As an example, the page unit may be larger than the sector unit. In a write operation, the buffer manager 1270 may manage data of the sector unit, which is received from the host 2000, in the page unit such that the received data can be written to the memory device 1100.

The response message control circuit 1240 may control the output time of a response message corresponding to a write request received from the host 2000 by monitoring the buffer memory 1220. As described above, when the utilization rate of the write buffer in the buffer memory 1220 is low, the response message control circuit 1240 may transfer the response message to the host 2000 by applying a relatively short response time. On the contrary, when the utilization rate of the write buffer in the buffer memory 1220 is high, the response message control circuit 1240 may transfer the response message to the host 2000 by applying a relatively long response time. The response message may be transferred to the host 2000 through the host interface 1260. A detailed operation and configuration of the response message control circuit 1240 will be described later with reference to FIGS. 4 and 5.

The memory controller 1200 may communicate with the external device (or the host 2000) through the host interface 1260. As an example, the host interface 1260 may include at least one of various interfaces such as a Universal Serial Bus (USB), a Multi-Media Card (MMC), an embedded MMC (eMMC), a Peripheral Component Interconnection (PCI), a PCI-Express (PCI-E), an Advanced Technology Attachment (ATA), a Serial-ATA (SATA), a Parallel-ATA (PATA), a Small Computer Small Interface (SCSI), an Enhanced Small Disk Interface (ESDI), Integrated Drive Electronics (IDE), Firewire, and a Universal Flash Storage (UFS).

The memory controller 1200 may communicate with the memory device 1100 through the memory interface 1280. As an example, the memory interface 1280 may include a NAND interface.

As an example, a write request and a read request, which are received from the host 2000, may be commands or signals defined by the host interface 1260. A write command and a read command, which are provided from the memory controller 1200 to the memory device 1100, may be commands or signals defined by the memory interface 1280.

Although not shown in FIG. 2, the memory controller 1200 may further include components such as a randomizer for data randomizing and an error correction circuit for data error correction.

FIG. 3 is a diagram illustrating the memory device of FIG. 1.

Referring to FIG. 3, the memory device 1110 may include a memory cell array 100 that stores data. The memory device 1110 may include peripheral circuits 200 configured to perform a program operation for storing data in the memory cell array 100, a read operation for outputting the stored data, and an erase operation for erasing the stored data. The memory device 1110 may include control logic 300 that controls the peripheral circuits 200 under the control of the memory controller (1200 of FIG. 1).

The memory cell array 100 may include a plurality of memory blocks MB1 to MBk (k is a positive integer) 110. Local lines LL and bit lines BL1 to BLn (n is a positive integer) may be coupled to the memory blocks MB1 to MBk 110. For example, the local lines LL may include a first select line, a second select line, and a plurality of word lines arranged between the first and second select lines. Also, the local lines LL may further include dummy lines arranged between the first select line and the word lines and between the second select line and the word lines. The first select line may be a source select line, and the second select line may be a drain select line. For example, the local lines LL may include word lines, drain and source select lines, and source lines SL. For example, the local lines LL may further include dummy lines. For example, the local lines LL may further include pipe lines. The local lines LL may be coupled to the memory blocks MB1 to MBk 110, respectively, and the bit lines BL1 to BLn may be commonly coupled to the memory blocks MB1 to MBk 110. The memory blocks MB1 to MBk 110 may be implemented in a two-dimensional or three-dimensional structure. For example, memory cells may be arranged in a direction parallel to a substrate in memory blocks 110 having a two-dimensional structure. For example, memory cells may be arranged in a direction vertical to a substrate in memory blocks 110 having a three-dimensional structure.

The peripheral circuits 200 may be configured to perform program, read, and erase operations of a selected memory block 110 under the control of the control logic 300. For example, the peripheral circuits 200, under the control of the control logic 300, may supply verify and pass voltages to the first select line, the second select line, and the word lines, selectively discharge the first select line, the second select line, and the word lines, and verify memory cells coupled a selected word line among the word lines. For example, the peripheral circuits 200 may include a voltage generating circuit 210, a row decoder 220, a page buffer group 230, a column decoder 240, an input/output circuit 250, and a sensing circuit 260.

The voltage generating circuit 210 may generate various operating voltages Vop used for program, read, and erase operations in response to an operation signal OP_CMD. Also, the voltage generating circuit 210 may selectively discharge the local lines LL in response to the operation signal OP_CMD. For example, the voltage generating circuit 210 may generate a program voltage, a verify voltage, pass voltages, a turn-on voltage, a read voltage, an erase voltage, a source line voltage, and the like under the control of the control logic 300.

The row decoder 220 may transfer the operating voltages Vop to local lines LL coupled to a selected memory block 110 in response to a row address RADD.

The page buffer group 230 may include a plurality of page buffers PB1 to PBn 231 coupled to the bit lines BL1 to BLn. The page buffers PB1 to PBn 231 may operate in response to page buffer control signals PBSIGNALS. For example, the page buffers PB1 to PBn 231 may temporarily store data received through the bit lines BL1 to BLn, or sense voltages or current of the bit lines BL1 to BLn in a read or verify operation.

The column decoder 240 may transfer data between the input/output circuit 250 and the page buffer group 230 in response to a column address CADD. For example, the column decoder 240 may exchange data with the page buffers 231 through data lines DL, or exchange data with the input/output circuit 250 through column lines CL.

The input/output circuit 250 may transfer a command CMD and an address ADD, which are received from the memory controller 1200 (of FIG. 1), to the control logic 300, or communicate data DATA with the column decoder 240.

In a read operation or verify operation, the sensing circuit 260 may generate a reference current in response to a permission bit VRY_BIT<#>, and output a pass signal PASS or a fail signal FAIL by comparing a sensing voltage VPB received from the page buffer group 230 with a reference voltage generated by the reference current.

The control logic 300 may control the peripheral circuits 200 by outputting the operation signal OP_CMD, the row address RADD, the page buffer control signals PBSIGNALS, and the permission bit VRY_BIT<#> in response to the command CMD and the address ADD. Also, the control logic 300 may determine whether the verify operation has passed or failed in response to the pass or fail signal PASS or FAIL.

FIG. 4 is a block diagram illustrating the memory controller 1200 according to an embodiment of the present disclosure. In FIG. 4, components for describing control of a response message according to an embodiment of the present disclosure are illustrated. For convenience, illustration and description of components less related to the control of the response message are omitted.

Referring to FIG. 4, the memory controller 1200 includes the host interface 1260, the write buffer 1225, the response message control circuit 1240, and the memory interface 1280. As described above, the memory controller 1200 may communicate with the host 2000 through the host interface 1260. Also, the memory controller 1200 may communicate with the memory device 1100 through the memory interface 1280.

The host 2000 transfers a write request WRQ and write data WDATA to the host interface 1260. The host interface 1260 transfers the write data WDATA to the write buffer 1225. The host interface 1260 may transfer the write request WRQ to the response message control circuit 1240.

The write buffer 1225 temporarily stores the write data WDATA received from the host interface 1260. As the write data WDATA is stored in the write buffer 1225, the response message control circuit 1240 generates a response message MSG_re and transfers the response message MSG_re to the host interface 1260. The host interface 1260 transfers the received response message MSG_re to the host 2000.

The write buffer 1225 transfers the stored write data WDATA to the memory interface 1280. The memory interface 1280 transfers the received write data WDATA together with a write command WCMD to the memory device 1100. The memory device 1100 may perform a write operation according to the received write command WCMD and the received write data WDATA.

The response message control circuit 1240 transfers a buffer control signal Bff_ctr to the write buffer 1225. The write buffer 1225 transfers buffer use information Bff_inf to the response message control circuit 1240, based on the received buffer control signal Bff_ctr. The buffer use information Bff_inf may include information on the utilization rate of the write buffer 1225. The response message control circuit 1240 determines the response time to be applied to output the response message MSG_re, based on the utilization rate. A more detailed configuration of the response message control circuit 1240 will be described later with reference to FIG. 5.

As described above, the utilization rate of the write buffer 1225 may be defined as a ratio of a total capacity of the write buffer 1225 to a current use of the write buffer 1225. In addition, the response time may be defined as a time interval from when the e request WRQ is provided to the controller 1200 from the host 2000 to when the response message MSG_re is transferred to the host 2000.

The response message control circuit 1240 according to an embodiment of the present disclosure may determine the response time to be relatively long when the utilization rate of the write buffer 1225 is relatively high. Accordingly, as the utilization rate of the write buffer 1225 increases, the host 2000 delays transfer of a new write request WRQ, so that the utilization rate of the write buffer 1225 can be maintained. Consequently, a variation in write latency between the host 2000 and the memory controller 1200 can be reduced, and thus the performance of the memory system 1000 can be improved.

FIG. 5 is a block diagram illustrating an embodiment of the response message control circuit 1240 of FIG. 4.

Referring to FIG. 5, the response message control circuit 1240 includes a buffer monitor 1241, a response time storage 1243, and a response message generator 1245.

The buffer monitor 1241 determines the response time tRSP by monitoring the utilization rate of the write buffer 1225. The response time storage 1243 stores the determined response time tRSP. The response message generator 1245 generates a response message MSG_re corresponding to the write request WRQ. Also, the response message generator 1245 outputs the generated response message MSG_re, based on the response time tRSP. In more detail, the response message generator 1245 may wait for the response time tRSP and then output the response message MSG_re. To this end, the response message generator 1245 may include a timer. The response message generator 1245 may check a point of time when the write request WRQ is received, based on the timer, and output the response message MSG_re when the response time tRSP elapses from when the write request WRQ is received. As shown in FIG. 4, the output response message MSG_re is transferred to the host 2000 through the host interface 1260.

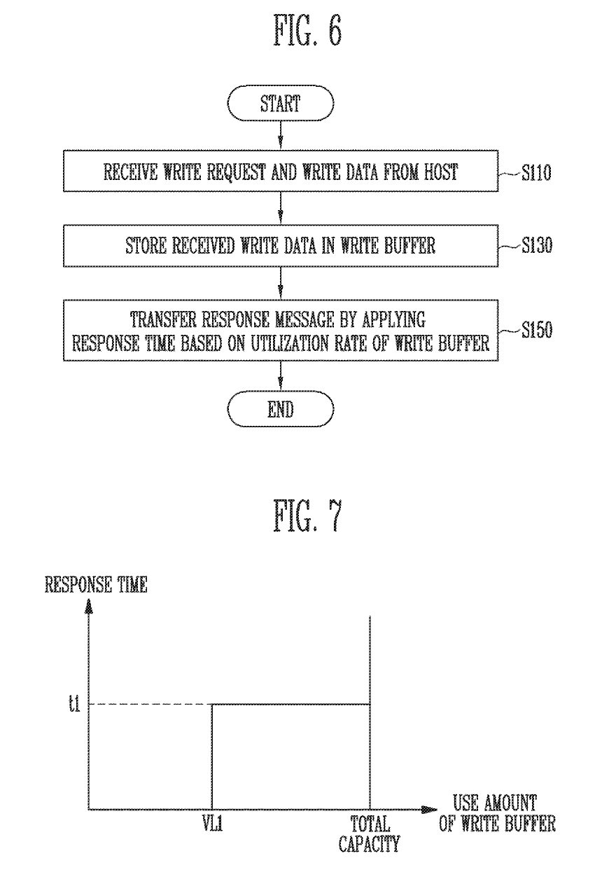

FIG. 6 is a flowchart illustrating an operating method of the memory controller 1200 according to an embodiment of the present disclosure.

Referring to FIG. 6, the memory controller 1200 transfers, to the host 2000, a response message corresponding to a write request received from the host 2000. The operating method is further described with reference to FIGS. 4 and 6 together.

In step S110, the memory controller 1200 receives a write request WRQ and write data WDATA from the host 2000. As shown in FIG. 4, the memory controller 1200 may receive the write request WRQ and the write data WDATA through the host interface 1260.

In step S130, the memory controller 1200 temporarily stores the received write data WDATA. Subsequently, the write data WDATA stored in the write buffer 1225 may be transferred together with a write command WCMD to the memory device 1100.

In step S150, the memory controller 1200 transfers a response message MSG_re to the host 2000 by applying a response time tRSP based on the utilization rate of the write buffer 1225. As described above, the memory controller 1200 according to an embodiment of the present disclosure may determine a relatively long response time tRSP when the utilization rate of the write buffer 1225 is relatively high.

FIG. 7 is a graph illustrating a response time determined according to an embodiment of the present disclosure.

Referring to the graph shown in FIG. 7, the horizontal axis represents a use amount of the write buffer 1225, and the vertical axis represents a response time tRSP determined according to the use amount. The use amount of the write buffer ranges from 0 to the total capacity of the write buffer. According to the embodiment shown in FIG. 7, when the use amount of the write buffer 1225 is less than or equal to a first value VL1, a response time of 0 is determined. That is, when the use amount of the write buffer 1225 is less than or equal to the first value VL1, the response message generator 1245 immediately outputs the response message MSG_re without any waiting time.

When the use amount of the write buffer 1225 is greater than the first value VL1, a first time t1 is determined as the response time tRSP. The first time t1 may be predetermined experimentally. For example, a value that allows the variation in write latency between the host 2000 and the memory controller 1200 to be minimized by repetitive simulations may be determined as the first time t1.

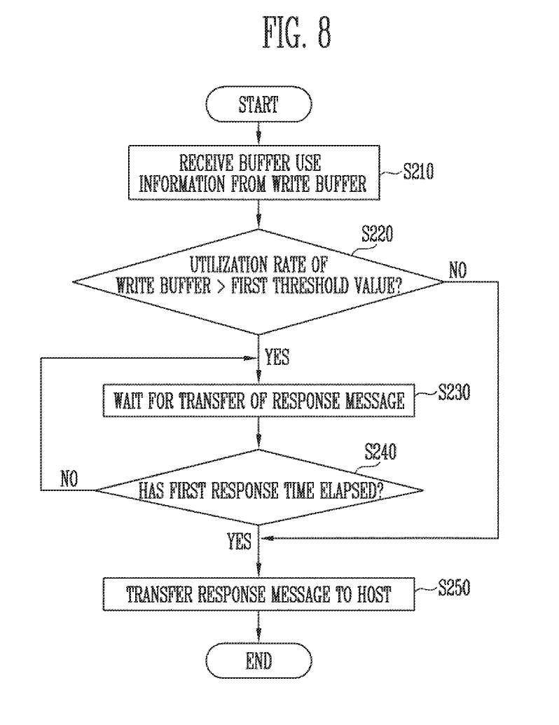

FIG. 8 is a flowchart illustrating a method for transferring a response message according to the embodiment shown in FIG. 7.

Referring to FIG. 8, in step S210, buffer use information Bff_inf is received from the write buffer 1225. The step 5210 may be performed by the response message control circuit 1240 of FIG. 4, more specifically, the buffer monitor 1241 of FIG. 5.

In step S220, it is determined whether the utilization rate of the write buffer is larger than a first threshold value. When the utilization rate of the write buffer is larger than the first threshold value (“YES” at step S220), this means that the use amount of the write buffer falls in the range between the first value VL1 and the total capacity as described with reference to FIG. 7. Accordingly, the first time t1 is determined as a first response time tRSP. Thus, the method proceeds to step S230.

In the step S230, there is a wait time before the transfer of the response message. Subsequently, it is determined in step S240 whether the first response time tRSP has elapsed. When the first response time tRSP has not elapsed (“NO” at step S240), the method returns to step S230 to continue to wait to the transfer the response message.

When the first response time tRSP elapses (“YES” at step S240), the response message MSG_re is transferred to the host 2000 in step S250. Accordingly, the response message MSG_re is transferred to the host 2000 after a delay of the first time t1.

When the utilization rate of the write buffer is less than or equal to the first threshold value (“NO” at step S220), the method immediately proceeds to the step S250. The response message MSG_re is immediately transferred to the host 2000 without waiting for any response time.

FIG. 9 is a flowchart illustrating a method for transferring a response message according to another embodiment of the present disclosure.

In step S310, buffer use information Bff_inf is received from the write buffer 1225. The step S310 may be performed by the response message control circuit 1240 of FIG. 4, more particularly, the buffer monitor 1241 of FIG. 5.

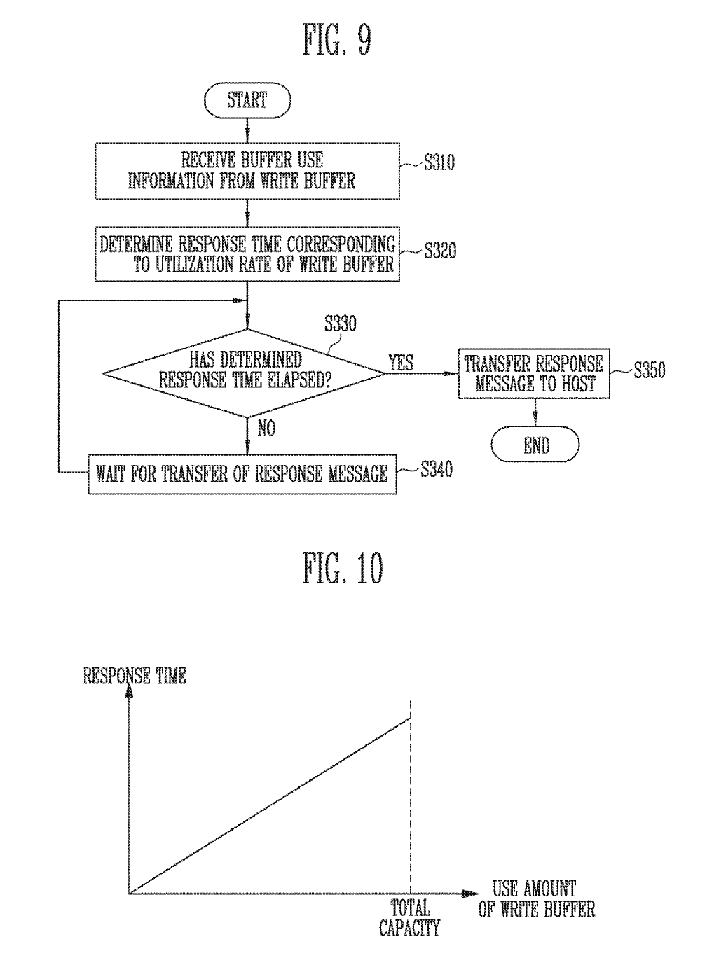

In step S320, the response time tRSP corresponding to the utilization rate of the write buffer is determined. The response time tRSP may be determined as shown in the graph of FIG. 7. However, the response time tRSP may be determined in various ways. A scheme for determining a response time tRSP corresponding to the utilization rate of the write buffer 1225 will be described in more detail below with reference to FIGS. 10 to 13.

In step S330, it is determined whether the response time tRSP has elapsed. When the response time tRSP has elapsed (“YES” at step S330), a response message MSG_re is transferred to the host 2000 at step S350. When the response time tRSP has not elapsed (“NO” at step S330), the transfer of the response message is delayed for a certain time at step S340, and the method returns to step S330 where it is determined whether the response time tRSP has elapsed.

FIG. 10 is a graph illustrating a response time that increases linearly in proportion to the utilization rate of the write buffer according to an embodiment of the present disclosure.

Referring to FIG. 10, the buffer monitor 1241 may determine a response time tRSP in proportion to a current use amount of the write buffer 1225 based on a linear expression.

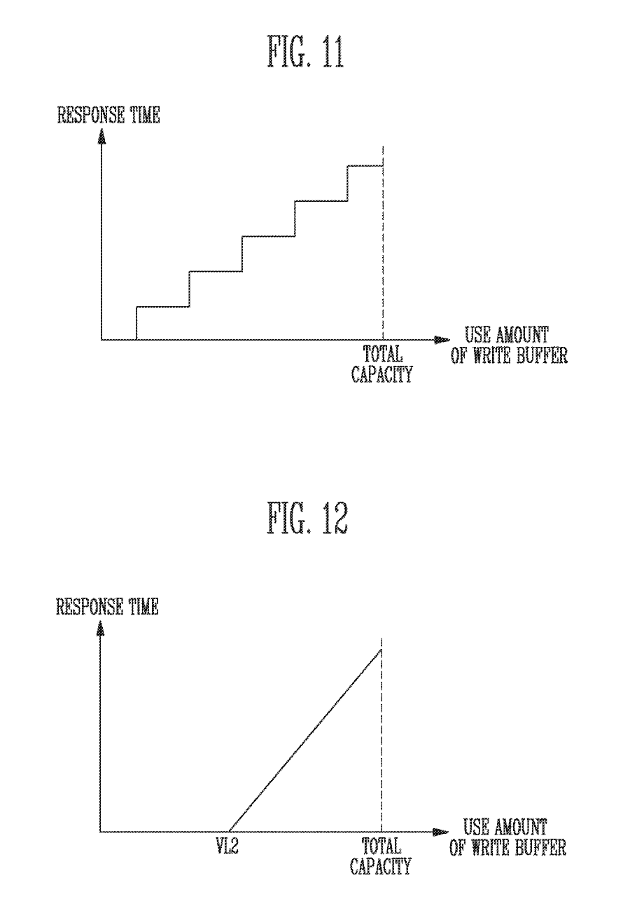

FIG. 11 is a graph illustrating a response time that increases in a stepwise manner in proportion to the utilization rate of the write buffer according to an embodiment of the present disclosure.

Referring to FIG. 11, the use amount of the write buffer 1225 is divided into a plurality of ranges, and the same response time tRSP may be applied to use amounts in the same range. When the use amount of the write buffer increases such that it falls in an adjacent, higher range, the response time tRSP is increased in a stepwise manner to the next step or level.

FIG. 12 is a graph illustrating a response time that linearly increases in a certain range of utilization rate of the write buffer according to an embodiment of the present disclosure.

Referring to FIG. 12, when the use amount of the write buffer 1225 is less than or equal to a second value VL2, which may be predetermined, the response time tRSP is 0. When the use amount of the write buffer 1225 is greater than the predetermined second value VL2, the response time tRSP linearly increases according to the use amount of the write buffer.

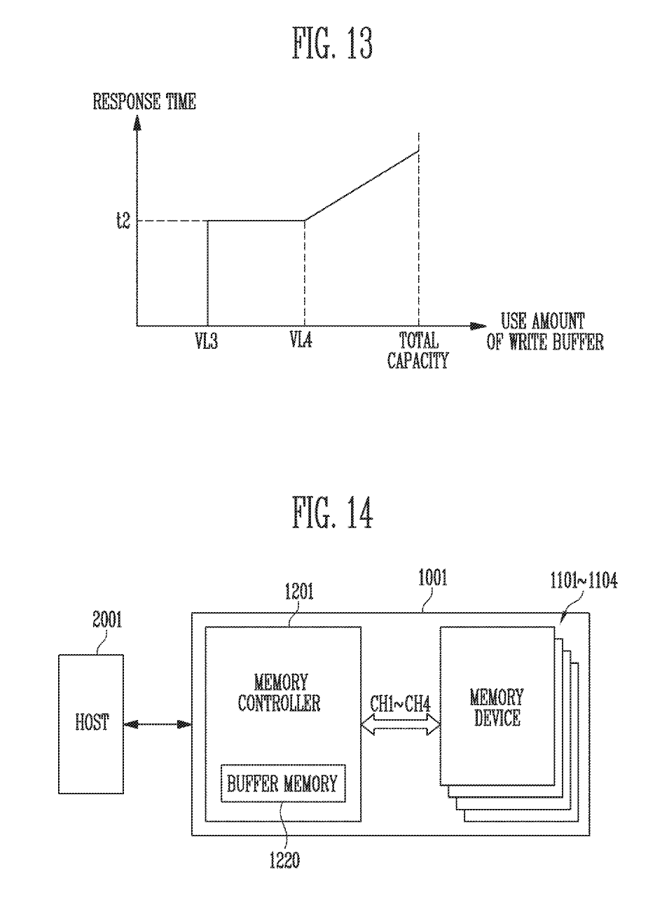

FIG. 13 is a graph illustrating different response times applied to three ranges obtained by dividing the utilization rate of the write buffer according to an embodiment of the present disclosure,

Referring to FIG. 13, when the use amount of the write buffer 1225 is less than or equal to a third value VL3, the response time tRSP is 0. When the use amount of the write buffer 1225 is greater than the third value VL3 and is less than or equal to a fourth value VL4, the response time tRSP is a second time t2. In a range in which the use amount of the write buffer 1225 is greater than the fourth value VL4, the response time tRSP linearly increases from t2 according to the use amount of the write buffer. The values VL3 and VL4 and the second time t2 may be predetermined.

As shown in FIGS. 7, 10, 11, 12, and 13, the response time tRSP may be determined in various ways according to the use amount of the write buffer 1225. However, the memory controller 1200 and the operating method thereof are not limited to these specific schemes; it will be understood that the response time tRSP may be determined in other ways that are not shown in FIGS. 7, 10, 11, 12, and 13.

FIG. 14 is a block diagram illustrating another embodiment of the memory system.

Referring to FIG. 14, the memory system 1001 includes a memory controller 1201 and first to fourth memory devices 1101 to 1104. A host 2001 and the memory controller 1201 have been described with reference to FIG. 1, and therefore, overlapping description thereof is omitted here. Similarly, buffer memory 1220 may also be substantially identical to the buffer memory 1220 described with reference to FIG. 1.

Each of the first to fourth memory devices 1101 to 1104 may be the memory device 1100 described with reference to FIGS. 1 and 3. The first to fourth memory devices 1101 to 1104 may be coupled to the memory controller 1201 respectively through first to fourth channels CH1 to CH4, and independently operate under the control of the memory controller 1201. For example, the plurality of memory devices 1101 to 1104 may simultaneously program different data. As an example, each of the plurality of memory devices 1101 to 1104 may be configured as an individual chip, and the plurality of memory devices 1101 to 1104 may be provided as a Multi-Chip Package (MCP).

As an example, the memory system 1101 may further include other memory devices in addition to the first to fourth memory devices 1101 to 1104.

The memory controller 1201 shown in FIG. 14 may also store data to be written to the first to fourth memory devices 1101 to 1104 in a write buffer of the buffer memory 1220. The memory controller 1201 determines a response time for a write request received from the host 2001 based on the utilization rate of the write buffer of the buffer memory 1220. Accordingly, a variation in write latency can be reduced. Consequently, the operation performance can be improved.

FIG. 15 is a diagram illustrating another embodiment of the memory system including the memory controller shown in FIGS. 1 and 2.

Referring to FIG. 15, the memory system 30000 may be implemented as a cellular phone, a smart phone, a tablet PC, a personal digital assistant (PDA), or a wireless communication device. The memory system 30000 may include a memory device 1100 and a memory controller 1200 capable of controlling an operation of the memory device 1100. The memory controller 1200 may control a data access operation of the memory device 1100, e.g., a program operation, an erase operation, a read operation, or the like under the control of a processor 3100.

Data programmed in the memory device 1100 may be output through a display 3200 under the control of the memory controller 1200.

A radio transceiver 3300 may transmit/receive radio signals through an antenna ANT. For example, the radio transceiver 3300 may convert a radio signal received through the antenna ANT into a signal that can be processed by the processor 3100. Therefore, the processor 3100 may process a signal output from the radio transceiver 3300 and transmit the processed signal to the memory controller 1200 or the display 3200. The memory controller 1200 may transmit the signal processed by the processor 3100 to the semiconductor memory device 1100. Also, the radio transceiver 3300 may convert a signal output from the processor 3100 into a radio signal, and output the converted radio signal to an external device through the antenna ANT. An input device 3400 is a device capable of inputting a control signal for controlling an operation of the processor 3100 or data to be processed by the processor 3100, and may be implemented as a pointing device such as a touch pad or a computer mount, a keypad, or a keyboard. The processor 3100 may control an operation of the display 3200 such that data output from the memory controller 1200, data output from the radio transceiver 3300, or data output from the input device 3400 can be output through the display 3200.

In some embodiments, the memory controller 1200 capable of controlling an operation of the memory device 1100 may be implemented as a part of the processor 3100, or be implemented as a chip separate from the processor 3100.

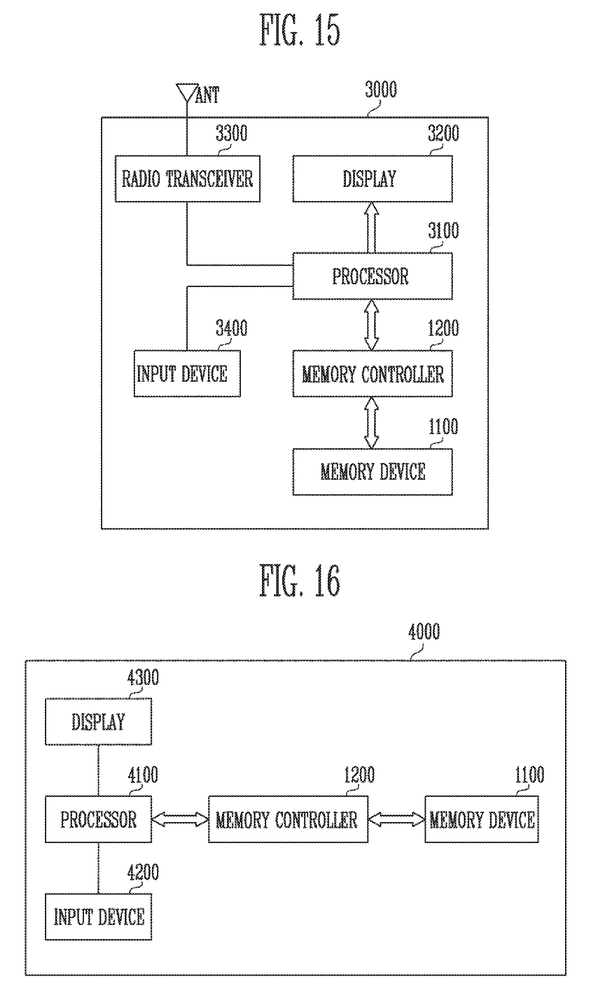

FIG. 16 is a diagram illustrating another embodiment of the memory system including the memory controller shown in FIGS. 1 and 2.

Referring to FIG. 16, the memory system 40000 may be implemented as a personal computer (PC), a tablet PC, a net-book, an e-reader, a personal digital assistant (PDA), a portable multimedia player (PMP), an MP3 player, or an MP4 player.

The memory system 40000 may include a memory device 1100 and a memory controller 1200 capable of controlling a data processing operation of the memory device 1100.

A processor 4100 may output data stored in the memory device 1100 through a display 4300 according to data input through an input device 4200. For example, the input device 4200 may be implemented as a pointing device such as a touch pad or a computer mouse, a keypad, or a keyboard.

The processor 4100 may control overall operations of the memory system 40000, and control an operation of the memory controller 1200. In some embodiments, the memory controller 1200 capable of controlling an operation of the memory device 1100 may be implemented as a part of the processor 4100, or be implemented as a chip separate from the processor 4100.

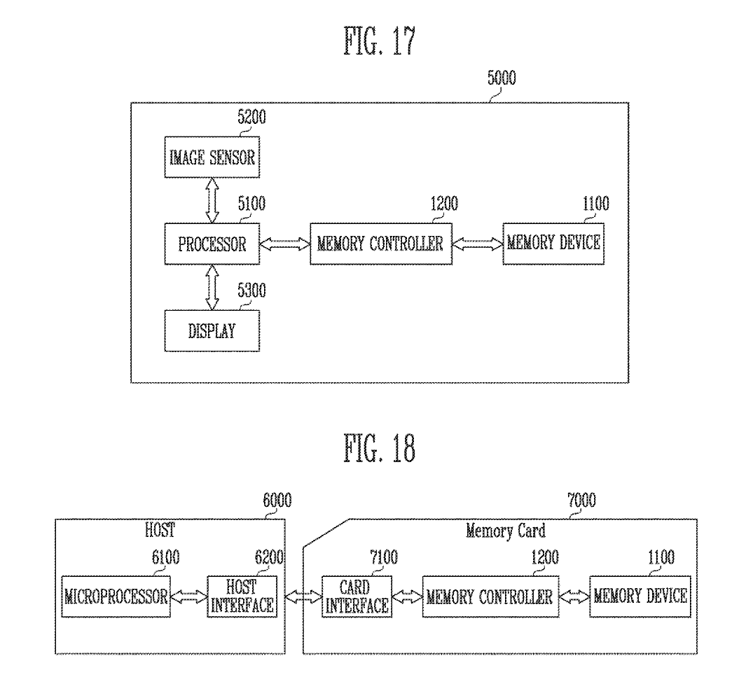

FIG. 17 is a diagram illustrating another embodiment of the memory system including the memory controller shown in FIGS. 1 and 2.

Referring to FIG. 17, the memory system 50000 may be implemented as an image processing device, e.g., a digital camera, a mobile terminal having a digital camera attached thereto, a smart phone having a digital camera attached thereto, or a tablet PC having a digital camera attached thereto.

The memory system 50000 may include a memory device 1100 and a memory controller 1200 capable of controlling a data processing operation of the memory device 1100, e.g., a program operation, an erase operation, or a read operation.

An image sensor 5200 of the memory system 50000 may convert an optical image into digital signals, and the converted digital signals may be transmitted to a processor 5100 or the memory controller 1200. Under the control of the processor 5100, the converted digital signals may be output through a display 5300, or be stored in the memory device 1100 through the memory controller 1200. In addition, data stored in the memory device 1100 may be output through the display 5300 under the control of the processor 5100 or the memory controller 1200.

In some embodiments, the memory controller 1200 capable of controlling an operation of the memory device 1100 may be implemented as a part of the processor 5100, or be implemented as a chip separate from the processor 5100.

FIG. 18 is a diagram illustrating another embodiment of the memory system including the memory controller shown in FIGS. 1 and 2.

Referring to FIG. 18, the memory system 70000 may be implemented as a memory card or a smart card. The memory system 70000 may include a memory device 1100, a memory controller 1200, and a card interface 7100.

The memory controller 1200 may control data exchange between the memory device 1100 and the card interface 7100. In some embodiments, the card interface 7100 may be a secure digital (SD) card interface or a multi-media card (MMC) interface, but the present disclosure is not limited thereto.

The card interface 7100 may interface data exchange between a host 60000 and the memory controller 1200 according to a protocol of the host 60000. In some embodiments, the card interface 7100 may support a universal serial bus (USB) protocol and an inter-chip (IC)-USB protocol. The card interface 7100 may mean hardware capable of supporting a protocol used by the host 60000, software embedded in the hardware, or a signal transmission scheme.

When the memory system 70000 is coupled to a host interface 6200 of the host 60000 such as a PC, a tablet PC, a digital camera, a digital audio player, a cellular phone, console video game hardware, or a digital set-top box, the host interface 6200 may perform data communication with the memory device 1100 through the card interface 7100 and the memory controller 1200 under the control of a microprocessor 6100.

FIG. 18 illustrates an embodiment in which the memory system 7000 is implemented with a memory card. However, the present disclosure is not limited thereto; the memory controller 1200 and the memory device 1100 may be integrated as one semiconductor device to constitute a Solid State Drive (SSD). The SSD may include a storage device configured to store data in a semiconductor memory.

According to embodiments of the present disclosure, a memory controller capable of reducing variation in write latency is provided.

Further, according to embodiments of the present disclosure, an operating method of a memory controller capable of reducing variation in write latency is provided.

Various embodiments have been disclosed herein, and although specific terms are employed, they are used and are to be interpreted in a generic and descriptive sense and not for purpose of limitation. In some instances, as would be apparent to one skilled in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A memory controller for controlling a write operation of a memory device in response to a write request received from a host, the memory controller comprising:
a write buffer configured to store write data received from the host together with the write request; and
a response message control circuit configured to generate a response message corresponding to the write request and transfer the response message to the host,
wherein the response message control circuit determines a response time to transfer the response message based on a utilization rate of the write buffer.

2. The memory controller of claim 1, wherein the utilization rate of the write buffer is defined as a ratio of a total capacity of the write buffer to a current use of the write buffer, and
the response time is defined as a time interval from when the write request is provided to the memory controller from the host to when the response message is transferred to the host.

3. The memory controller of claim 2, wherein the response time is determined to be relatively long when the utilization rate of the write buffer is relatively high.

4. The memory controller of claim 3, wherein the response message control circuit:
when the utilization rate of the write buffer is less than or equal to a first threshold value, determines the response time to be 0 and immediately transfers the response message to the host when the write data is stored in the write buffer; and
when the utilization rate of the write buffer is greater than the first threshold value, determines a first time as the response time.

5. The memory controller of claim 2, wherein the response message control circuit includes:
a buffer monitor configured to determine the response time by monitoring the utilization rate of the write buffer;
a response time storage configured to store the response time; and
a response message generator configured to generate a response message corresponding to the write request, and output the response message based on the response time stored in the response time storage.

6. The memory controller of claim 5, wherein the buffer monitor determines the response time in proportion to the utilization rate of the write buffer.

7. The memory controller of claim 5, wherein the buffer monitor determines the response time in a stepwise manner with respect to the utilization rate of the write buffer.

8. The memory controller of claim 5, wherein the buffer monitor:
when the utilization rate of the write buffer is less than or equal to a second threshold value, determines the response time to be 0; and
when the utilization rate of the write buffer is greater than the second threshold value, determines the response time as a linear function with respect to the utilization rate of the write buffer.

9. The memory controller of claim 5, wherein the buffer monitor:
when the utilization rate of the write buffer is less than or equal to a third threshold value, determines the response time to be 0;
when the utilization rate of the write buffer is greater than the third threshold value and is less than a fourth threshold value, determines the is response time to be a second time; and
when the utilization rate of the write buffer is greater than the fourth threshold value, determines the response time as a linear function with respect to the utilization rate of the write buffer.

10. A method for operating a memory controller for controlling an operation of a memory device, the method comprising:
receiving, from a host, a write request and write data corresponding thereto;
storing the write data in a write buffer; and
transferring a response message corresponding to the write request to the host according to a response time determined based on a utilization rate of the write buffer.

11. The method of claim 10, wherein the transferring of the response message corresponding to the write request to the host according to the response time determined based on the utilization rate of the write buffer includes:
receiving the utilization rate from the write buffer;
determining whether the utilization rate is greater than a first threshold value; and
transferring a response message to the host based on a determination result.

12. The method of claim 11, wherein, in the transferring of the response message to the host based on the determination result,
when the utilization rate is greater than the first threshold value, the response message is transferred to the host after waiting a first time period, and
when the utilization rate is less than or equal to the first threshold value, the response message is immediately transferred to the host.

13. The method of claim 10, wherein the transferring of the response message corresponding to the write request to the host according to the response time determined based on the utilization rate of the write buffer includes:
receiving the utilization rate from the write buffer;
determining the response time corresponding to the utilization rate, wherein the determined response time includes a first wait time; and
transferring the response message to the host after the first wait time elapses.

14. The method of claim 13, wherein, in the determining of the response time, the response time is determined in proportion to the utilization rate.

15. The method of claim 13, wherein, in the determining of the response time, the response time is determined in a stepwise manner with respect to the utilization rate.

16. The method of claim 13, wherein, in the determining of the response time,
when the utilization rate is less than or equal to a second threshold value, the response time is determined to be immediate, and
when the utilization rate is greater than the second threshold value, the response time is determined as a linear function with respect to the utilization rate.

17. The method of claim 13, wherein, in the determining of the response time,
when the utilization rate is less than or equal to a third threshold value, the response time is determined to be immediate,
when the utilization rate is greater than the third threshold value and is less than a fourth threshold value, the response time is determined to include a second wait time, and
when the utilization rate is greater than the fourth threshold value, the response time is determined as a linear function with respect to the utilization rate.

18. A memory system comprising:
a memory device;
a buffer configured to buffer data provided from an external source; and
a controller configured to:
control the memory device to perform a write operation with the buffered data in response to a request from the external source; and
provide a response of the request to the external source at a response time, which is after the controller receives the request,
wherein the controller determines the response time based on a currently available capacity of the buffer.
